(19) United States
(12) Patent Application Publication
(10) Pub. No.: US 2021/0105587 A1
(43) Pub. Date: Apr. 8, 2021

(54) AUTOMATIC LEVEL CONTROL FOR HALF DUPLEX RADIO

(71) Applicant: SAPURA SECURED TECHNOLOGIES SDN BHD, Kuala Lumpur (MY)

(72) Inventors: David John Beaton PEARCE, Kuala Lumpur (MY); Muhd Nordin bin MOHAMED, Kuala Lumpur (MY)

(73) Assignee: SAPURA SECURED TECHNOLOGIES SDN BHD, Kuala Lumpur (MY)

(21) Appl. No.: 17/013,719

(22) Filed: Sep. 7, 2020

(30) Foreign Application Priority Data
Oct. 3, 2019 (MY) PI 2019005862

(51) Int. Cl. H04W 4/10; H04W 52/52; H04L 5/16

(52) U.S. Cl. CPC H04W 4/10; H04L 5/16; H04W 52/52

(57) ABSTRACT

An automatic level control system for providing stabilized voice output in a radio is provided herein. The automatic level control system includes a push to talk detect section configured to detect pressing of a push to talk input section by a user. The automatic level control system further includes a level detector section configured to detect a present ‘gain’ of the automatic level control system. The automatic level control system further includes a gain decision section configured to determine a ‘gain’, based on the gain detected by the level detector section, and pressing detected by the push to talk detect section. The automatic level control system further includes a gain control section configured to receive voice input from the user through a voice input section and gain parameter from the gain decision section, and provide a stabilized voice output through the voice output section.

### FIELD OF THE INVENTION

Embodiments of the present invention, generally relate to a half-duplex radio, and in particular relate to automatic voice level control for half duplex radio.

### BACKGROUND

Radios commonly use automatic level controls to provide a uniform audio level despite the large range in microphone output due to mouth distance and voice loudness. A half-duplex radio uses push-to-talk (PTT) to transmit. A typical automatic level control (ALC) detects a voice level, and filters the voice level to obtain an average level. The average level is compared with a reference and variable gain amplifier is controlled in a feedback loop. Overall objective of the feedback loop is to adjust the gain so that for a large range of talker volume, a constant output level could be achieved.

However, the push to talk (PTT) radio has several problems with this conventional automatic level control approach. Normally, the microphone is only powered when the PTT key is pressed. A consequence of this is that when the radio is not transmitting, the automatic level control (ALC) circuit goes to a maximum gain. When the PTT is released, the variable gain amplifier gradually ramps to maximum gain.

When PTT is pressed and the user or talker starts, output is initially clipped, until the feedback loop recovers. This forces the use of fast loop time constant, with audible side effects on gaps between words. Further, some radio microphones produce a voltage spike when PTT is pressed. This can cause gain to be reduced. Longer time constants may avoid this, but longer time constant conflict with voltage spike when PTT is pressed.

Therefore, there is a need for an improved automatic level control for half duplex radio that can solve above mentioned problems associated with conventional level controls.

### SUMMARY

According to an aspect of the present disclosure, an automatic level control system for providing stabilized voice output in a radio is provided herein. The automatic level control system includes a push to talk detect section 106 configured to detect pressing of a push to talk input section 104 by a user. The automatic level control system further includes a level detector section 108 configured to detect a present ‘gain’ of the automatic level control system. The automatic level control system further includes a gain decision section 110 configured to determine a ‘gain’, based on the gain detected by the level detector section 108, and pressing detected by the push to talk detect section 106. The automatic level control system further includes a gain control section 112 configured to receive voice input from the user through a voice input section 102 and gain parameter from the gain decision section 110, and provide a stabilized voice output through the voice output section 114.

According to another aspect of the present disclosure, a method for providing automatic level control of a radio and providing stabilized voice output from the radio is provided herein. The method includes detecting, by a push to talk detect section, push to talk pressing by a user, and receiving voice input from the user. Further, the method includes detecting a present ‘gain’ of the automatic level control system. The method further includes determining a ‘gain’ of the automatic level control system, based on the pressing detecting by the push to talk detect section, and the received present ‘gain’ from the level detector section. The method further includes controlling gain of the automatic level control system, based on the determined gain, and providing stable voice output from the voice output section.

The preceding is a simplified summary to provide an understanding of some aspects of embodiments of the present invention. This summary is neither an extensive nor exhaustive overview of the present invention and its various embodiments. The summary presents selected concepts of the embodiments of the present invention in a simplified form as an introduction to the more detailed description presented below. As will be appreciated, other embodiments of the present invention are possible utilizing, alone or in combination, one or more of the features set forth above or described in detail below.

### BRIEF DESCRIPTION OF THE DRAWINGS

The above and still further features and advantages of embodiments of the present invention will become apparent upon consideration of the following detailed description of embodiments thereof, especially when taken in conjunction with the accompanying drawings, and wherein:

FIG. 1 illustrates a schematic diagram of an automatic level control system for providing stabilized voice output, according to an embodiment of the present invention;

FIG. 2 illustrates performance of automatic level control system against conventional control system, according to an embodiment of the present invention; and

FIG. 3 depicts an exemplary flowchart illustrating a method for automatically controlling voice level in half duplex radio, according to an embodiment of the present invention.

To facilitate understanding, like reference numerals have been used, where possible, to designate like elements common to the figures.

### DETAILED DESCRIPTION

As used throughout this application, the word “may” is used in a permissive sense (i.e., meaning having the potential to), rather than the mandatory sense (i.e., meaning must). Similarly, the words “include”, “including”, and “includes” mean including but not limited to.

The phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising”, “including”, and “having” can be used interchangeably.

The term “automatic” and variations thereof, as used herein, refers to any process or operation done without material human input when the process or operation is performed. However, a process or operation can be automatic, even though performance of the process or operation uses material or immaterial human input, if the input is received before performance of the process or operation. Human input is deemed to be material if such input influences how the process or operation will be performed. Human input that consents to the performance of the process or operation is not deemed to be “material”.

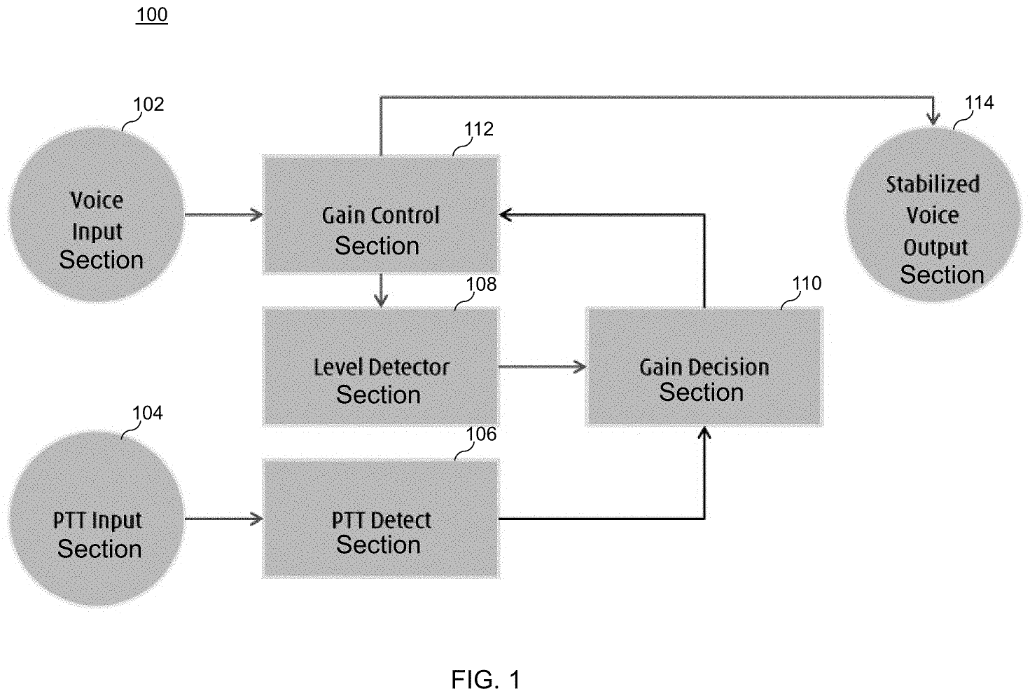

FIG. 1 illustrates a schematic representation of an automatic level control system 100 for providing stabilized voice output in half duplex radio. In an embodiment, the automatic level control (ALC) system is configured to adjust volume over a radio or intercom independently of mouth to microphone distance, speech volume etc.

In an embodiment of the present disclosure, the automatic level control system 100 includes a voice input section 102 and a push to talk (PTT) input section 104. In an embodiment, the voice input section 102 and the push to talk (PTT) input section 104 are configured to enable a user to provide voice input to the automatic level control system 100. In an embodiment, the user is required to press the push to talk (PTT) input section 104 before providing voice input via the voice input section 102.

The automatic level control system 100 further includes a PTT detect section 106. In an embodiment, the PTT detect section 106 is coupled or connected with the PTT input section 104. The PTT detect section 106 is configured to detect pressing of the PTT input section 104 by the user, as the user is required to press the push to talk (PTT) input section 104 before providing voice input.

The automatic level control system 100 further includes a level detector section 108, a gain decision section 110, a gain control section 112, and a stabilized voice output section 114. In an embodiment, the voice input section 102 is connected to the gain control section 112. Further, the gain control section 112 is connected to the level detector section 108. The level detector section 108 is connected to the gain decision section 110. Further, the PTT detect section 106 is connected to the gain decision section 110. The gain decision section 110 is connected to the gain control section 112. The gain control section 112 is connected to the output section that is configured to provide stabilized voice output.

In an embodiment, the level detector section 108 is configured to detect a present or current ‘gain’ (for example, voltage gain) of the circuit or the automatic level control system 100. Further, the level detector section 108 is configured to provide the detected present gain to the gain decision section 110. The gain decision section 110 is configured to determine a ‘gain’ based on the input received from the push to talk detect section 106 and the received gain from the level detector section 108.

According to an embodiment of the present invention, the gain decision section 110 is configured to use a digitally controlled gain block in the control loop. Those skilled in the art will appreciate that the digitally controlled gain block may be either a hardware circuit using a digital potentiometer or in digital signal processing (DSP) software.

Further, the gain decision section 110 is configured to provide the determined gain to the gain control section 112. In an embodiment, the gain control section 112 may include a processor, a memory having suitable programs that can be executed by the processor. The gain control section 112 is configured to utilize the received gain in controlling output section 114. In an embodiment, the output section 114 is configured to provide stabilized voice output based on the received gain from the gain control section 112.

Further, in an embodiment, the output section 114 of the automatic level control system 100 is configured to use a microcontroller (not shown in figure) to measure output speech level at the output section 114. The automatic level control system 100 is further configured to digitally control the gain to allow a stable output level, as described above. Further, the microcontroller is configured to determine the gain based on the detected level. Further, in an embodiment, the gain is frozen when the push to talk input section (104) is not pressed. In an embodiment, when the push to talk input section (104) is released, the gain is frozen. Those skilled in the art will appreciate that this may prevent gain going to maximum in idle time.

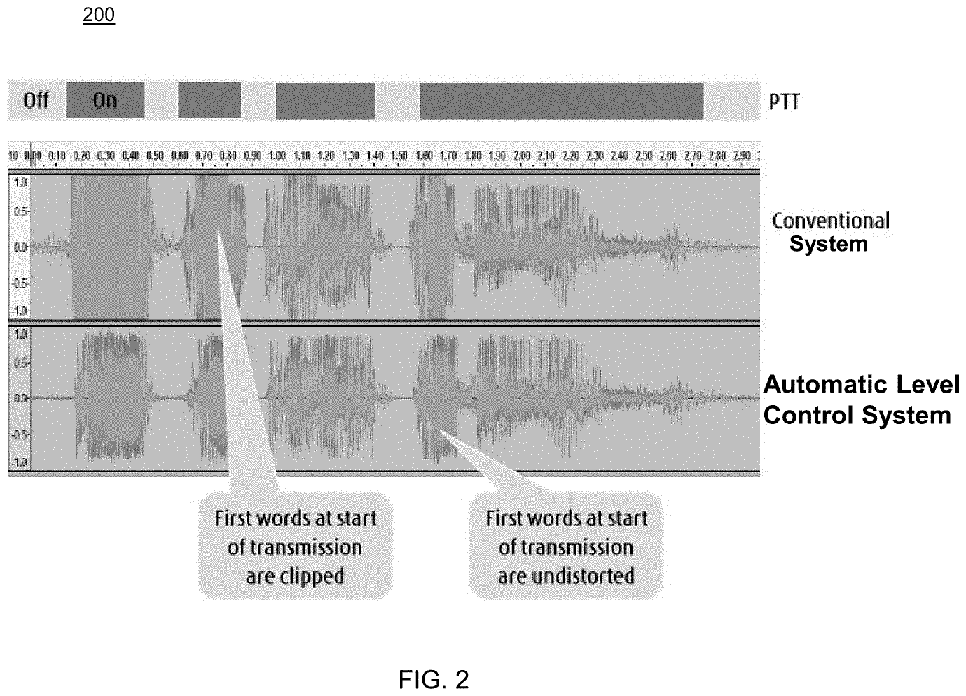

FIG. 2 depicts performance of automatic level control system controlling gain digitally. As shown in FIG. 2, in a conventional voice level control system, first words at start of transmission are clipped. However, the automatic level control system 100, as provided by present invention, provides undistorted first words at start of transmission. In an embodiment, when the push to talk input section (104) is next pressed by the user, the automatic level control system gain loop is configured to resumes at previous level. Those skilled in the art will appreciate that the automatic level control gain is more likely to be already correct, since it was frozen, and it will improve the intelligibility of the first few syllables in the voice output.

Further, in an embodiment, the level detector section 108 may be briefly inhibited to mask the start-up spike. Those skilled in the art will appreciate that this allows a longer averaging time, and reduces audible pumping effects. Further, when the speech is started again, the gain will be near to the correct value, and hence clipping will be avoided. Further, the gain may be adjusted during push to talk (PTT) active phases by the automatic level control system 100.

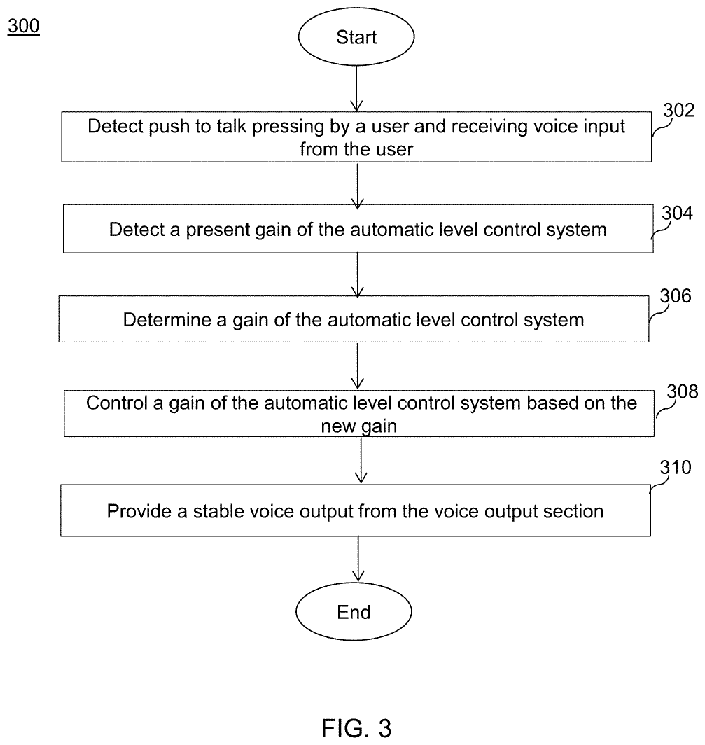

FIG. 3 illustrates an exemplary flowchart 300 for a method of automatically controlling voice level in half duplex radio, according to an embodiment of the present disclosure. Initially, at step 302, the push to talk pressing by the user is detected, and voice input from the user is received. In an embodiment, the user may provide the voice input via the voice input section 102, after pressing the push to talk (PTT) input section 104. Further, the push to talk button pressing may be detected by the push to talk detect section 106.

At step 304, a present ‘gain’ of the automatic level control system is detected. In an embodiment, a voltage gain of the automatic level control system may be detected by the level detector section 108. At step 306, a gain of the automatic level control system is determined. In an embodiment, the gain decision section 110 may determine the gain based on the input received from the push to talk detect section 106 and the received gain from the level detector section 108. In an embodiment, the gain decision section 110 may use a digitally controlled gain block in the control loop.

At step 308, the gain of the automatic level control system is controlled based on the gain. In an embodiment, the gain control section 112 may utilize the received gain in controlling gain of the automatic level control system 100. At step 310, stable voice output is provided from the voice output section. In an embodiment, the output section 114 may provide stabilized voice output based on the received gain from the gain control section 112.

The automatic level control system 100 and the method 300 advantageously improve the intelligibility of the first few syllables in the voice output, and thus provide undistorted first words at start of transmission, unlike clipped first words at start of transmission as provided by conventional voice level control system.

Furthermore, the disclosed invention has been illustrated in use with a push to talk input section and voice input section, and other sections as described in FIG. 1. It will be appreciated that the invention may be used with modulators, radio-frequency and analogous amplifiers which are subject to automatic level control. Accordingly, the invention is applicable to electronic signal devices having a fixed amplitude output at one or a band of frequencies, the amplitude of which being controlled by automatic level control devices.

The foregoing discussion of the present invention has been presented for purposes of illustration and description. It is not intended to limit the present invention to the form or forms disclosed herein. In the foregoing Detailed Description, for example, various features of the present invention are grouped together in one or more embodiments, configurations, or aspects for the purpose of streamlining the disclosure. The features of the embodiments, configurations, or aspects may be combined in alternate embodiments, configurations, or aspects other than those discussed above. This method of disclosure is not to be interpreted as reflecting an intention the present invention requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate embodiment of the present invention.

Moreover, though the description of the present invention has included description of one or more embodiments, configurations, or aspects and certain variations and modifications, other variations, combinations, and modifications are within the scope of the present invention, e.g., as may be within the skill and knowledge of those in the art, after understanding the present disclosure. It is intended to obtain rights which include alternative embodiments, configurations, or aspects to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

1. An automatic level control system for providing stabilized voice output in a radio, the automatic level control system comprising:
a push to talk detect section configured to detect pressing of a push to talk input section by a user;
a level detector section configured to detect a present ‘gain’ of the automatic level control system;
a gain decision section configured to determine a ‘gain’, based on the gain detected by the level detector section, and pressing detected by the push to talk detect section; and
a gain control section configured to receive voice input from the user through a voice input section and gain parameter from the gain decision section, and provide a stabilized voice output through the voice output section.

2. The automatic level control system of claim 1, wherein the level detector section is configured to detect a voltage gain of the automatic level control system.

3. The automatic level control system of claim 1, wherein the gain decision section is configured to use a digitally controlled gain block in the control loop.

4. The automatic level control system of claim 3, wherein the digitally controlled gain block is a hardware circuit having a digital potentiometer.

5. The automatic level control system of claim 1, wherein the gain control section having a processor and a memory, and the memory having suitable programs that are executable by the processor.

6. The automatic level control system of claim 1, wherein the output section is configured to use a microcontroller to measure output speech level.

7. The automatic level control system of claim 1, wherein the gain decision section is configured to freeze the gain when the push to talk input section is not pressed.

8. The automatic level control system of claim 1, wherein the output section configured to provide undistorted first words at start of transmission of voice output.

9. A method for providing automatic level control of a radio and providing stabilized voice output from the radio, the method comprising:
detecting, by a push to talk detect section, push to talk pressing by a user, and receiving voice input from the user;
detecting a present ‘gain’ of the automatic level control system;
determining a ‘gain’ of the automatic level control system, based on the pressing detecting by the push to talk detect section, and the received present ‘gain’ from the level detector section; and
controlling gain of the automatic level control system, based on the determined gain, and providing stable voice output from the voice output section.

10. The method of claim 9, wherein the detecting comprising detecting a voltage gain.

11. The method of claim 9, wherein the determining comprising using a digitally controlled gain block in the control loop.

12. The method of claim 9, wherein the providing stable voice output comprising providing undistorted first words at start of transmission of voice output.

13. The method of claim 9, wherein the providing stable voice output comprising using a microcontroller to measure output speech level.

14. The method of claim 9, wherein the determining the ‘gain’ comprising freezing the gain when the push to talk input section is released by the user.

15. The method of claim 9, wherein the controlling gain comprising digitally controlling the gain to allow a stable voice output level.
